(19) United States
(12) Patent Application Publication
(10) Pub. No.: US 2025/0096519 A1
(43) Pub. Date: Mar. 20, 2025

(54) LIGHT-EMITTING DEVICE

(71) Applicant: NICHIA CORPORATION, Anan-shi (JP)

(72) Inventor: Hiroaki YUTO, Awa-shi (JP)

(73) Assignee: NICHIA CORPORATION, Anan-shi (JP)

(21) Appl. No.: 18/882,322

(22) Filed: Sep. 11, 2024

(30) Foreign Application Priority Data
Sep. 15, 2023 (JP) 2023-150318

(51) Int. Cl. H01S 5/02208; H01S 5/02255; H01S 5/0236; H01S 5/042

(52) U.S. Cl. CPC H01S 5/02208; H01S 5/02255; H01S 5/0236; H01S 5/04256

(57) ABSTRACT

A light-emitting device according to an embodiment of the present disclosure includes: a light-emitting element; a base having an upper surface opposite to a lower surface of the light-emitting element, the base directly or indirectly supporting the light-emitting element; a lid body having a flat plate-like shape and having a lower surface opposite to an upper surface of the light-emitting element; and a first frame portion located on the upper surface of the base and surrounding the light-emitting element, in which the base includes a first conductor portion bonded to the lower surface of the light-emitting element, the lid body includes a second conductor portion bonded to the upper surface of the light-emitting element, and the first frame portion is directly or indirectly bonded to the lid body.

### CROSS-REFERENCE TO RELATED APPLICATIONS

The present application claims priority under 35 U.S.C. § 119 to Japanese Patent Application No. 2023-150318, filed Sep. 15, 2023, the contents of which are hereby incorporated by reference in its entirety.

### BACKGROUND

### 1. Technical Field

The present disclosure relates to a light-emitting device.

### 2. Description of Related Art

P.C.T. Publication No. WO 2021/256421 (“Patent Document 1”) discloses a light-emitting device including a semiconductor light-emitting chip, a first submount and a second submount respectively connected to both surfaces of the semiconductor light-emitting chip, and a first side wall and a second side wall provided between the first submount and the second submount. Further, in Patent Document 1, the first side wall is provided, the second side wall is provided, and then a light-transmissive member is bonded to the first side wall and the second side wall to hermetically seal the semiconductor light-emitting chip.

### SUMMARY

An object of the present disclosure is to simplify a manufacturing process of a light-emitting device.

A light-emitting device according to an embodiment of the present disclosure includes: a light-emitting element; a base having an upper surface opposite to a lower surface of the light-emitting element, the base directly or indirectly supporting the light-emitting element; a lid body having a flat plate-like shape and having a lower surface opposite to an upper surface of the light-emitting element; and a first frame portion provided on the upper surface of the base and surrounding the light-emitting element, in which the base includes a first conductor portion bonded to the lower surface of the light-emitting element, the lid body includes a second conductor portion bonded to the upper surface of the light-emitting element, and the first frame portion is directly or indirectly bonded to the lid body.

According to an embodiment of the present disclosure, a manufacturing process of a light-emitting device can be simplified.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic perspective view illustrating an example of a light-emitting device according to a first embodiment.

FIG. 2 is a schematic perspective view of the light-emitting device illustrated in FIG. 1, from which a lid body and a second frame portion are removed.

FIG. 3 is a schematic perspective view of the light-emitting device illustrated in FIG. 1, from which a base and a first frame portion are removed.

FIG. 4 is a schematic bottom view illustrating an example of the light-emitting device according to the first embodiment.

FIG. 5 is a schematic perspective view of a light-emitting device including a modified example of the first frame portion.

FIG. 6 is a schematic cross-sectional view illustrating a cross section and a current path of the light-emitting device taken along a cross-sectional line VI-VI in FIG. 1.

FIG. 7 is a schematic perspective view illustrating an example of a light-emitting device according to a second embodiment.

FIG. 8 is a schematic perspective view of the light-emitting device illustrated in FIG. 7, from which a lid body and a second frame portion are removed.

FIG. 9 is a schematic perspective view of the light-emitting device illustrated in FIG. 7, from which a base and a first frame portion are removed.

FIG. 10 is a schematic cross-sectional view illustrating a cross section and a current path of the light-emitting device taken along a cross-sectional line X-X in FIG. 7.

FIG. 11 is a schematic perspective view illustrating an example of a light-emitting device according to a third embodiment.

FIG. 12 is a schematic perspective view of the light-emitting device illustrated in FIG. 11, from which a lid body and a second frame portion are removed.

FIG. 13 is a schematic perspective view of the light-emitting device illustrated in FIG. 11, from which a base and a first frame portion are removed.

FIG. 14 is a schematic transparent view illustrating an example of the light-emitting device and a current path according to the third embodiment.

FIG. 15 is a schematic perspective view illustrating an example of a light-emitting device according to a fourth embodiment.

FIG. 16 is a schematic transparent view illustrating an example of the light-emitting device and a current path according to the fourth embodiment.

FIG. 17 is a schematic perspective view illustrating an example of a light-emitting device according to a fifth embodiment.

FIG. 18 is a schematic transparent view illustrating an example of the light-emitting device and a current path according to the fifth embodiment.

FIG. 19 is a schematic perspective view illustrating an example of a light-emitting device according to a sixth embodiment.

FIG. 20 is a schematic transparent view illustrating an example of the light-emitting device and a current path according to the sixth embodiment.

FIG. 21 is a schematic perspective view illustrating an example of a light-emitting device according to a seventh embodiment.

### DETAILED DESCRIPTION

### Description of Embodiments

Hereinafter, embodiments for carrying out the invention will be described with reference to the drawings. In the following description, terms indicating a specific direction or position (e.g., “upper,” “lower,” and other terms including those terms) are used as necessary. The use of those terms, however, is to facilitate understanding of the invention with reference to the drawings, and the technical scope of the present invention is not excessively limited by the meanings of those terms. For example, when “upper surface” is described, the invention does not always have to be used so that the “upper surface” faces upward. Parts having the same reference signs appearing in a plurality of drawings indicate identical or equivalent parts or members.

In the present disclosure, polygons such as triangles and quadrangles, including shapes in which the corners of the polygon are rounded, chamfered, beveled, coved, and the like, are referred to as polygons. A shape obtained by processing not only the corners (ends of a side) but also an intermediate portion of the side is similarly referred to as a polygon. That is, a shape that is partially processed while leaving the polygon as the base is included in the interpretation of the “polygon” described in the present disclosure.

The same applies not only to polygons but also to the terms representing specific shapes such as trapezoids, circles, protrusions, and recessions. The same also applies to the terms related to each side forming the shape. That is, even when processing is performed on a corner or an intermediate portion of a certain side, the interpretation of “side” includes the processed portion. When a “polygon” or a “side” not partially processed is to be distinguished from a processed shape, “strict” will be added to the description as in, for example, “strict quadrangle.”

The following embodiments exemplify light-emitting devices for embodying the technical concept of the present invention, and the present invention is not limited to the description below. In addition, dimensions, materials, shapes, relative arrangements, and the like of constituent parts described below are not intended to limit the scope of the present invention thereto but are merely exemplary, unless otherwise specified. The contents described in one embodiment can be applied to the other embodiment and modified examples. The sizes, positional relationship, and the like of the members illustrated in the drawings can be exaggerated in order to clarify the explanation. In addition, in order to avoid the drawings from being excessively complicated, schematic diagrams in which illustration of some constituent parts is omitted may be used. An end view illustrating only a cut surface may be used as a schematic cross-sectional view.

In each of the drawings, an X-axis, a Y-axis, and a Z-axis orthogonal to each other are illustrated for reference. A direction parallel to the X-axis is referred to as an X direction. In addition, in the X direction, a direction in which an arrow is directed is referred to as a +X direction, and a direction opposite to the +X direction is referred to as a −X direction. In the Y direction, a direction in which an arrow is directed is referred to as a +Y direction, and a direction opposite to the +Y direction is referred to as a −Y direction. In the Z direction, a direction in which an arrow is directed is referred to as a +Z direction, and a direction opposite to the +Z direction is referred to as a −Z direction. However, this does not limit the orientation of the light-emitting device during use, and the orientation of the light-emitting device may be any chosen orientation.

In the present specification or the claims, when a plurality of components are present and these components are to be indicated separately, the components may be distinguished by adding the terms “first” and “second” at the beginning of the names of the components. Objects to be distinguished may differ between the present specification and the claims. Thus, even when a component in the claims is given the same term as that in the present specification, the object identified by that component is not the same across the present specification and the claims in some cases.

For example, in the present specification, there are components distinguished by being appended with “first,” “second,” and “third,” and in the present specification, when components appended with “first” and “third” are described in the claims, or when components appended with “first” and components not appended with specific ordinal numbers are described in the claims, the components may be distinguished by being appended with “first” and “second” in the claims from the viewpoint of visibility. In this case, in the claims, components denoted by “first” and “second” respectively indicate components denoted by “first” and “third,” or components not denoted by specific ordinal numbers in the present specification. This rule applies to not only components but also other objects in a reasonable and flexible manner.

### First Embodiment

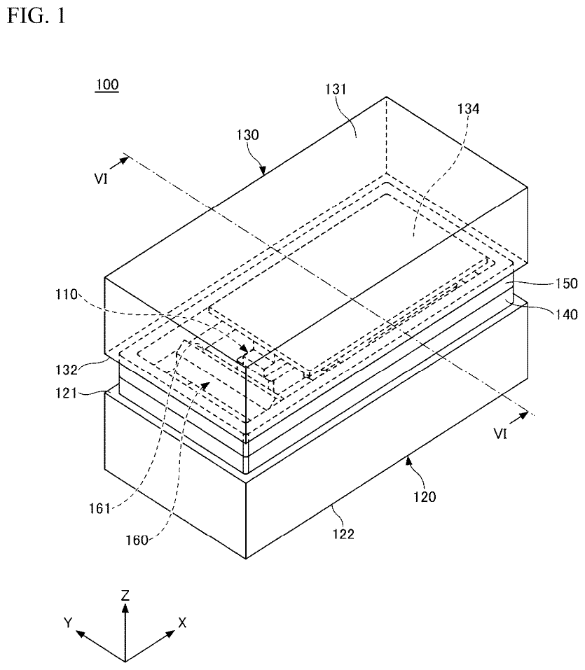

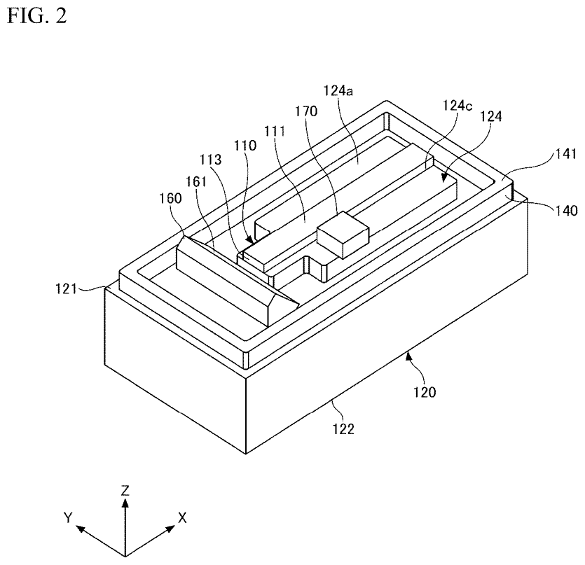

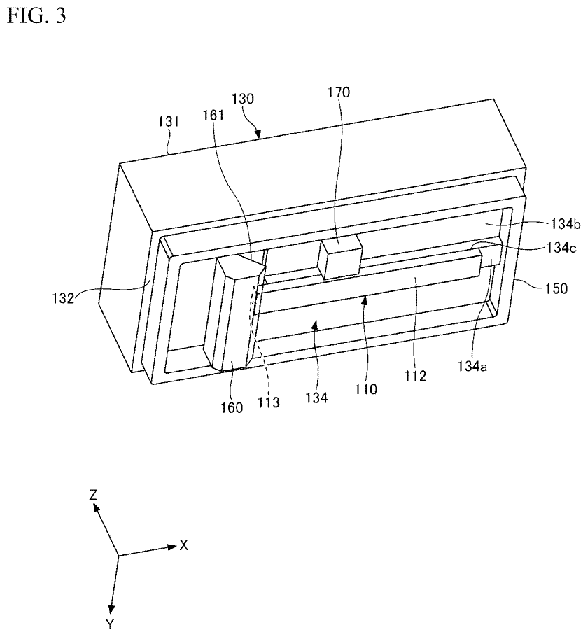

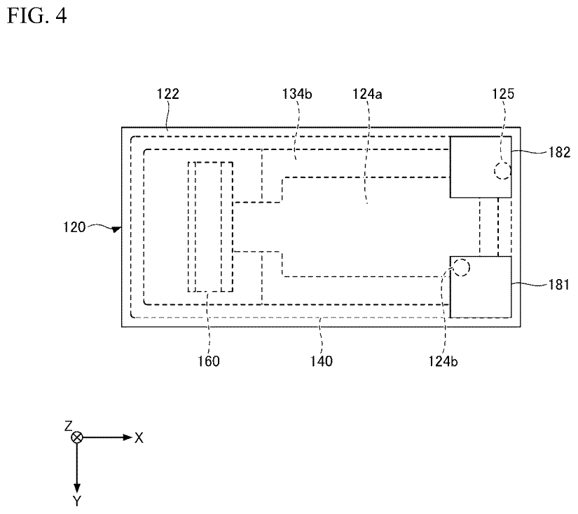

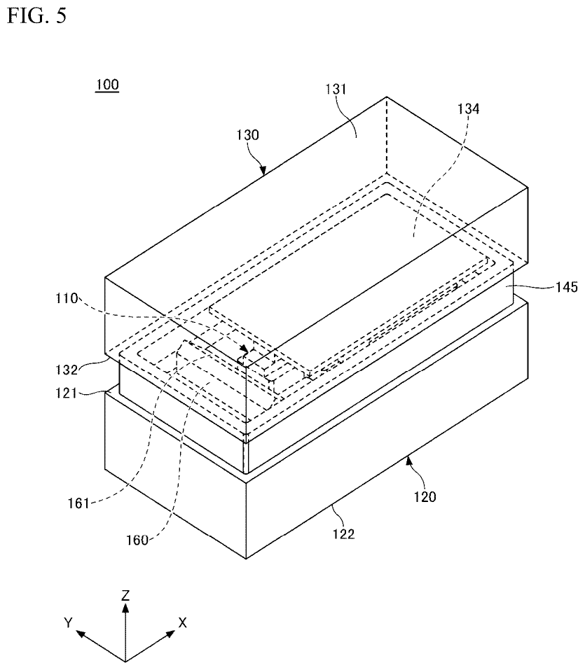

A configuration example of the light-emitting device 100 according to the first embodiment will be described with reference to FIGS. 1 to 5. FIG. 1 is a schematic perspective view illustrating an example of the light-emitting device 100 according to the first embodiment. FIG. 2 is a schematic perspective view of the light-emitting device 100 illustrated in FIG. 1, from which a lid body 130 and a second frame portion 150 are removed. FIG. 3 is a schematic perspective view of the light-emitting device 100 illustrated in FIG. 1, from which a base 120 and a first frame portion 140 are removed. FIG. 4 is a schematic bottom view of the light-emitting device 100. FIG. 5 is a schematic perspective view of the light-emitting device 100 including the first frame portion of a modified example (first frame portion 145).

As illustrated in FIGS. 1 to 4, the light-emitting device 100 according to the present embodiment includes a light-emitting element 110, the base 120, the lid body 130, and the first frame portion 140. The light-emitting device 100 may further include a second frame portion 150, a light reflective member 160, a protective element 170, a first electrode 181, and a second electrode 182. Hereinafter, each configuration included in the light-emitting device 100 will be described in detail.

### Light-Emitting Element 110

The light-emitting element 110 is a light source of the light-emitting device 100. The light-emitting element 110 of the present embodiment is, for example, a semiconductor laser element including an n-type cladding layer, an active layer, and a p-type cladding layer which are sequentially layered in the Z direction. However, the type of the light-emitting element 110 is not limited to the semiconductor laser element. Other examples of the light-emitting element 110 include a light-emitting diode (LED) and an organic light-emitting diode (OLED).

The light-emitting element 110 has an upper surface 111 (surface on the +Z direction side) and a lower surface 112 (surface on the −Z direction side). The light-emitting element 110 has one or more lateral surfaces connected to the upper surface 111 and the lower surface 112. The one or more lateral surfaces connect the outer edges of the upper surface 111 and the lower surface 112.

The light-emitting element 110 of the present embodiment has a rectangular parallelepiped outer shape extending along the X direction. However, the light-emitting element 110 is not limited to one having a rectangular parallelepiped outer shape, and may have another shape.

Each of the upper surface 111 and the lower surface 112 of the light-emitting element 110 of the present embodiment is a flat surface having a rectangular outer shape. A rectangle includes a square unless specifically stated to exclude a square. However, the outer shapes of the upper surface 111 and the lower surface 112 of the light-emitting element 110 are not limited to a rectangle. The outer shapes of the upper surface 111 and the lower surface 112 of the light-emitting element 110 may be any shape such as a circle, an ellipse, or a polygon in a top view. The “top view” refers to a view of an object from the +Z direction side. Hereinafter, the same applies to the “top view.”

The light-emitting element 110 has four lateral surfaces. Each lateral surface of the light-emitting element 110 is a flat surface having a rectangular outer shape. Among the four lateral surfaces of the light-emitting element 110, a lateral surface 113 which is disposed on the −X direction side and faces the light reflective member 160 corresponds to a light-emitting surface which emits light. Hereinafter, the lateral surface 113 that emits light is referred to as a “light-emitting surface 113.”

The light-emitting element 110 emits visible light. Examples of the light-emitting element that emits visible light include a light-emitting element that emits blue light, a light-emitting element that emits green light, and a light-emitting element that emits red light. The light-emitting element that emits blue light refers to a light-emitting element that emits light having emission peak wavelengths in a range from 405 nm to 494 nm. The light-emitting element that emits green light refers to a light-emitting element that emits light having emission peak wavelengths in a range from 495 nm to 570 nm. The light-emitting element that emits red light refers to a light-emitting element that emits light having emission peak wavelengths in a range from 605 nm to 750 nm.

An example of the light-emitting element 110 that emits blue light or green light is a semiconductor laser element including a nitride semiconductor. Examples of the nitride semiconductor include GaN, InGaN, and AlGaN. Examples of the light-emitting element 110 that emits red light include a semiconductor laser element including an InAlGaP-based semiconductor, a GaInP-based semiconductor, a GaAs-based semiconductor, or an AlGaAs-based semiconductor.

However, the color of the light emitted from the light-emitting element 110 may be a color different from blue, green, and red. The light emitted from the light-emitting element 110 is not limited to visible light, and may be ultraviolet light or infrared light.

### Base 120

The base 120 is a member that is disposed on the −Z direction side with respect to the light-emitting element 110 and directly or indirectly supports the light-emitting element 110. Here, the configuration of “directly supporting the light-emitting element 110” refers to a configuration in which the base 120 and the light-emitting element 110 are bonded to each other with a bonding material or without using a bonding material. On the other hand, the configuration of “indirectly supporting the light-emitting element 110” refers to a configuration in which the light-emitting element 110 is bonded to another member with a bonding material or without using a bonding material, and the base 120 supports the other member, whereby the light-emitting element 110 is supported via the another member.

In the base 120 of the present embodiment, the length in the X direction is greater than the length in the Y direction. The base 120 of the present embodiment has a rectangular parallelepiped outer shape. However, the base 120 is not limited to one having a rectangular parallelepiped outer shape, and may have another shape.

The base 120 includes an upper surface 121 (surface on the +Z direction side), a lower surface 122 (surface on the −Z direction side), four lateral surfaces connecting outer edges of the upper surface 121 and the lower surface 122, and a first conductor portion 124.

Each of the upper surface 121 and the lower surface 122 of the base 120 is a flat surface having a rectangular outer shape. However, the outer shapes of the upper surface 121 and the lower surface 122 of the base 120 are not limited to rectangles. The outer shapes of the upper surface 121 and the lower surface 122 of the base 120 may be any shape such as a circle, an ellipse, or a polygon in a top view. Each lateral surface of the base 120 is also a flat surface having a rectangular outer shape.

The base 120 includes, for example, an insulating material. Examples of insulating materials include aluminum nitride, silicon nitride, aluminum oxide, and silicon carbide. The base 120 may include an insulating region made of an insulating material and a conductive region made of a conductive material. However, an insulating region is disposed in a portion of the base 120 that is in contact with the first conductor portion 124.

The first conductor portion 124 includes an outer layer portion 124a which is disposed on the upper surface 121 side of the base 120 and to which the lower surface 112 of the light-emitting element 110 is bonded, and a first inner layer wiring line 124b which is disposed on the −Z direction side of the outer layer portion 124a and is provided inside the base 120.

The outer layer portion 124a is a flat plate-like conductor portion that is thick in the Z direction and has a length in the X direction greater than a length in the Y direction. The outer layer portion 124a includes a plurality of regions having different lengths in the X-direction. In the present embodiment, the central region of the plurality of regions of the outer layer portion 124a is the longest in the X direction and extends to the vicinity of the light reflective member 160. Further, the light-emitting element 110 is bonded to the central region.

As an example, as illustrated in FIG. 2, the central region of the outer layer portion 124a includes a region that protrudes in the −X direction relative to the other two regions. The light-emitting element 110 is bonded to at least a region protruding in the −X direction in the central region of the outer layer portion 124a. Further, the light-emitting surface 113 of the light-emitting element 110 is disposed in the vicinity of the end portion on the −X direction side in the central region of the outer layer portion 124a in the top view. Thus, the light-emitting surface 113 of the light-emitting element 110 can be brought close to a light reflective surface 161 of the light reflective member 160. As a result, the size of the light-emitting device 100 can be reduced.

Among the plurality of regions included in the outer layer portion 124a, two regions having a length in the X direction smaller than the length in the X direction of the central region are disposed on the +Y direction side and the −Y direction side, respectively, with the central region interposed therebetween. In the present embodiment, the protective element 170 is bonded to a region on the −Y direction side with respect to the central region. The light-emitting element 110 and the protective element 170 are electrically connected via the outer layer portion 124a.

However, the outer layer portion 124a need not include a plurality of regions having different lengths in the X-direction. The outer layer portion 124a may be, for example, a flat plate-like portion having a rectangular outer shape in a top view. The positions of the light-emitting element 110 and the protective element 170 on the outer layer portion 124a are not limited.

The first inner layer wiring line 124b is a conductor portion extending in the Z direction. The upper end (end portion on the +Z direction side) of the first inner layer wiring line 124b is connected to the lower surface (surface on the −Z direction side) of the outer layer portion 124a. As illustrated in FIG. 4, the lower end (end portion on the −Z direction side) of the first inner layer wiring line 124b is connected to the first electrode 181. That is, the first inner layer wiring line 124b electrically connects the outer layer portion 124a and the first electrode 181. Note that the first inner layer wiring line 124b is not limited to one having a shape extending in the Z direction. The first inner layer wiring line 124b may have a shape that is bent at one or more positions.

The upper surface (surface on the +Z direction side) of the outer layer portion 124a is bonded to the lower surface 112 of the light-emitting element 110. That is, the first conductor portion 124 electrically connects the light-emitting element 110 and the first electrode 181.

The base 120 may further include a second inner layer wiring line 125 provided inside the base 120 and extending in the Z direction. The second inner layer wiring line 125 is a conductor portion parallel to the first inner layer wiring line 124b in the Z direction. The second inner layer wiring line 125 need not be parallel to the first inner layer wiring line 124b in the Z direction. Further, the second inner layer wiring line 125 is not limited to one having a shape extending in the Z direction. The second inner layer wiring line 125 may have a shape that is bent at one or more positions. Note that “parallel” includes an error of ±5° in the angle between the objects. Hereinafter, the same applies to “parallel.”

An upper end (end portion on the +Z direction side) of the second inner layer wiring line 125 is connected to a lower surface (surface on the −Z direction side) of the first frame portion 140. On the other hand, the lower end (end portion on the −Z direction side) of the second inner layer wiring line 125 is connected to the second electrode 182. That is, the second inner layer wiring line 125 electrically connects the first frame portion 140 and the second electrode 182. As illustrated in FIG. 4, at least a part of the lower end of the second inner layer wiring line 125 overlaps the first frame portion 140 in the bottom view. On the other hand, the lower end of the first inner layer wiring line 124b does not overlap the first frame portion 140 and is disposed on an inner side of the first frame portion 140 in the bottom view.

### First Frame Portion 140

The first frame portion 140 is disposed on an outer side of the light-emitting element 110 on the upper surface 121 of the base 120, and is a rectangular ring-like member surrounding the light-emitting element 110 in a top view. The first frame portion 140 protrudes from the upper surface 121 of the base 120 toward the +Z direction side.

In the present embodiment, the first frame portion 140 protrudes to the +Z direction side from the upper surface 121 of the base 120 as a starting point. However, the connection configuration between the first frame portion 140 and the base 120 is not limited thereto. For example, the first frame portion 140 and the base 120 may be connected to each other in a state where a part of the lower side (−Z direction side) of the first frame portion 140 is embedded in the base 120.

In the present embodiment, the first frame portion 140 is disposed near the outer edge of the upper surface 121 of the base 120. However, the position of the first frame portion 140 is not limited thereto. The first frame portion 140 is disposed surrounding the light-emitting element 110.

The first frame portion 140 includes a conductive region made of a conductive material. The entire first frame portion 140 of the present embodiment is made of a conductive material. However, the configuration of the first frame portion 140 is not limited thereto. The first frame portion 140 may include a conductive region and an insulating region. When the first frame portion 140 includes a conductive region and an insulating region, the conductive region of the first frame portion 140 is connected to the second inner layer wiring line 125.

As illustrated in FIG. 1, an upper surface (surface on the +Z direction side) of the first frame portion 140 is bonded to a lower surface (surface on the −Z direction side) of the second frame portion 150. The light-emitting element 110 is hermetically sealed in a space defined by the base 120, the lid body 130, the first frame portion 140, and the second frame portion 150.

### Modified Example of First Frame Portion

The first frame portion 140 according to the basic example illustrated in FIGS. 1 and 2 is bonded to the second frame portion 150. On the other hand, the first frame portion 145 according to a modified example illustrated in FIG. 5 is bonded to the lower surface 132 (surface on the −Z direction side) of the lid body 130. That is, when the first frame portion 145 according to the modified example is used, the second frame portion 150 can be omitted. In this case, the light-emitting element 110 is hermetically sealed in a space defined by the base 120, the lid body 130, and the first frame portion 145.

A configuration in which the second frame portion 150 is omitted and the first frame portion 145 and the lid body 130 are bonded to each other as in the modified example corresponds to a configuration in which “the first frame portion is directly bonded to the lid body.” In contrast, as in the basic example, the configuration in which the second frame portion 150 is interposed between the first frame portion 140 and the lid body 130 corresponds to the configuration in which “the first frame portion is indirectly bonded to the lid body.”

### Lid Body 130

As illustrated in FIG. 1, the lid body 130 is a flat plate-like member that is disposed on the +Z direction side of the light-emitting element 110 and the base 120 and covers the upper surface 111 of the light-emitting element 110 and the upper surface 121 of the base 120. However, the lid body 130 is a member that covers at least the first frame portion 140 and the second frame portion 150 in the top view. The lid body 130 includes an upper surface 131 (surface on the +Z direction side), the lower surface 132 (surface on the −Z direction side), one or a plurality of lateral surfaces connecting outer edges of the upper surface 131 and the lower surface 132, and a second conductor portion 134. The lower surface 132 of the lid body 130 faces the upper surface 111 of the light-emitting element 110.

The lid body 130 of the present embodiment has a rectangular parallelepiped outer shape having a length in the X direction greater than a length in the Y direction. However, the lid body 130 is not limited to one having a rectangular parallelepiped outer shape, and may have another shape.

Each of the upper surface 131 and the lower surface 132 of the lid body 130 of the present embodiment is a flat surface having a rectangular outer shape. However, each of the outer shapes of the upper surface 131 and the lower surface 132 of the lid body 130 are not limited to a rectangular shape. The outer shapes of the upper surface 131 and the lower surface 132 of the lid body 130 may be any shape such as a circular shape, an elliptical shape, or a polygonal shape in a top view.

The lid body 130 of the present embodiment has four lateral surfaces. Each of the four lateral surfaces of the lid body 130 connects different outer edges of the upper surface 131 and the lower surface 132. In addition, each of four lateral surfaces of the lid body 130 is also a flat surface having a rectangular outer shape.

The lid body 130 includes a light-transmitting region which transmits light emitted from the light-emitting surface 113 of the light-emitting element 110. The light-transmitting region is disposed in a region through which light emitted from the light-emitting surface 113 of the light-emitting element 110 and reflected upward by the light reflective member 160 passes.

In the present embodiment, the lid body 130 includes a material having visible light transmissivity, such as quartz or glass.

As illustrated in FIG. 3, the second conductor portion 134 includes a first layer 134a bonded to the upper surface 111 of the light-emitting element 110 and a second layer 134b connected to the upper surface (surface on the +Z direction side) of the first layer 134a. Each of the first layer 134a and the second layer 134b is a flat plate-like conductor portion that has a thickness in the Z direction and is longer in the X direction than in the Y direction. The first layer 134a and the second layer 134b may be made of the same conductive material or may be made of different conductive materials.

The first layer 134a has a strip-like outer shape extending parallel to the light-emitting element 110 along the X-direction. The lateral surface of the first layer 134a on the +X direction side is connected to the second frame portion 150. That is, the first layer 134a electrically connects the light-emitting element 110 and the second frame portion 150.

The second layer 134b has a flat plate-like outer shape such that the length in the Y direction is greater than the length in the Y direction of the first layer 134a. In a top view, a portion of the lower surface (surface on the −Z direction side) of the second layer 134b does not overlap the upper surface of the first layer 134a. A portion of the lower surface of the second layer 134b that does not overlap the first layer 134a is bonded to the upper surface (surface on the +Z direction side) of the protective element 170.

In the second layer 134b, at least one of the three lateral surfaces excluding the lateral surface on the −X direction side is connected to the second frame portion 150. That is, the second layer 134b electrically connects the protective element 170 and the second frame portion 150. However, when the light-emitting device 100 does not include the protective element 170, the second layer 134b may be omitted. In addition, when the thickness of the light-emitting element 110 and the thickness of the protective element 170 are the same as each other, the first layer 134a may be omitted, and the second layer 134b may be bonded to each of the light-emitting element 110 and the protective element 170.

As illustrated in FIG. 3, the lateral surface of the first layer 134a on the −X direction side and the lateral surface of the second layer 134b on the −X direction side are disposed at substantially the same position in the X direction. On the other hand, the light-emitting surface 113 of the light-emitting element 110 is located at a position further separated in the −X direction side from the lateral surface of the first layer 134a on the −X direction side and the lateral surface of the second layer 134b on the −X direction side. That is, in the top view, the second conductor portion 134 is provided at a position away from the light-emitting surface 113 of the light-emitting element 110 in the +X direction. Accordingly, it is possible to suppress the light emitted from the light-emitting surface 113 of the light-emitting element 110 from being vignetted by the second conductor portion 134.

### Second Frame Portion 150

As illustrated in FIG. 3, the second frame portion 150 is a rectangular ring-like member which protrudes from the lower surface 132 of the lid body 130 to the −Z direction side. The second frame portion 150 is disposed on an outer side of the light-emitting element 110 in a top view and surrounds the light-emitting element 110.

In the present embodiment, the second frame portion 150 protrudes to the −Z direction side from the lower surface 132 of the lid body 130 as a starting point. However, the connection configuration between the second frame portion 150 and the lid body 130 is not limited thereto. For example, the second frame portion 150 and the lid body 130 may be connected to each other in a state where a part of the upper side (+Z direction side) of the second frame portion 150 is embedded in the lid body 130.

In the present embodiment, the second frame portion 150 is disposed near the outer edge of the lower surface 132 of the lid body 130, and is disposed at a position overlapping the first frame portion 140. However, the position of the second frame portion 150 is not limited thereto. In a state where the upper surface 121 of the base 120 and the lower surface 132 of the lid body 130 face each other, the second frame portion 150 is disposed at least on an outer side of the light-emitting element 110. The width of the second frame portion 150 may be the same as or different from the width of the first frame portion.

The second frame portion 150 includes a conductive region made of a conductive material. The entire second frame portion 150 of the present embodiment is made of a conductive material. However, the configuration of the second frame portion 150 is not limited thereto. The second frame portion 150 may include a conductive region and an insulating region. When the second frame portion 150 includes a conductive region and an insulating region, the conductive region of the second frame portion 150 is bonded to each of the second conductor portion 134 and the conductive region of the first frame portion 140.

### Light Reflective Member 160

The light reflective member 160 is a member that reflects light emitted from the light-emitting surface 113 of the light-emitting element 110 toward the light-transmitting region of the lid body 130. As illustrated in FIG. 1, the light reflective member 160 includes the light reflective surface 161, a lower surface, and a plurality of lateral surfaces intersecting with the light reflective surface 161 and the lower surface. In the present embodiment, each of the light reflective surface 161, the lower surface, and the plurality of lateral surfaces is a flat surface.

The light reflective surface 161 faces the light-emitting surface 113 of the light-emitting element 110. The light reflective surface 161 reflects the light emitted from the light-emitting surface 113 toward the light-transmitting region of the lid body 130. The light reflective surface 161 is an inclined plane, but is not limited thereto as long as the light emitted from the light-emitting surface 113 can be reflected to the lid body 130 side. For example, the light reflective surface 161 may be a curved surface or may include a flat surface region and a curved surface region.

Glass, metal, or the like can be used as a main material for forming the outer shape of the light reflective surface 161. The main material is preferably a heat-resistant material, and, for example, glass such as quartz and BK7 (borosilicate glass), metal such as aluminum, or Si can be used. The light reflective surface 161 can be formed using, for example, a metal such as Ag or Al, or a dielectric multilayer film of Ta₂O₅/SiO₂, TiO₂/SiO₂, Nb₂O₅/SiO₂, or the like.

However, in the light-emitting element 110, for example, in a case in which the upper surface 111 is a light-emitting surface and no member that blocks light emitted from the upper surface 111 is interposed between the upper surface 111 and the lid body 130, the light reflective member 160 need not be provided.

### Protective Element 170

The protective element 170 is a component for protecting the light-emitting element 110. For example, the protective element 170 is a component for preventing the light-emitting element 110 from being broken due to excessive current that flows thereto. As the protective element 170, for example, a Zener diode is used. Further, the protective element 170 may be a component for measuring the temperature of the light-emitting element 110 itself or the temperature in the vicinity of the light-emitting element 110. By providing the protective element 170 as the temperature measuring element, for example, it is possible to suppress a situation in which the light-emitting element 110 is exposed to an excessively high temperature environment and breaks down. Examples of the temperature measuring element include a thermistor. When the protective element 170 is used as a temperature measuring element, it is preferably disposed near the light-emitting surface 113 of the light-emitting element 110.

The protective element 170 has an upper surface and a lower surface. The lower surface of the protective element 170 is bonded to the upper surface of the outer layer portion 124a provided on the upper surface 121 of the base 120, similarly to the lower surface 112 of the light-emitting element 110. The upper surface of the protective element 170 is bonded to the second layer 134b of the second conductor portion 134 provided on the lower surface 132 of the lid body 130.

### Bonding Layer

In the present embodiment, when different constituent parts are bonded to each other, the constituent parts may be bonded to each other via a bonding layer formed by curing a conductive adhesive. Such a configuration in which the constituent parts are bonded to each other via the bonding layer is included in the configuration in which the constituent parts are “directly bonded” to each other or the configuration in which the constituent parts are “directly supported” by each other.

Examples of the bonding layer include a bonding layer 124c disposed between the light-emitting element 110 and the outer layer portion 124a of the first conductor portion 124, the bonding layer disposed between the protective element 170 and the outer layer portion 124a of the first conductor portion 124, the bonding layer 134c disposed between the light-emitting element 110 and the first layer 134a of the second conductor portion 134, the bonding layer disposed between the protective element 170 and the second layer 134b of the second conductor portion 134, and a bonding layer 141 disposed between the first frame portion 140 and the second frame portion 150. The plurality of bonding layers may be made of the same material or may be made of different materials. For example, a bonding layer made of AuSn or the like may be used.

When the constituent parts are bonded to each other through the bonding layer, the interface resistance between the constituent parts can be reduced. In addition, by bonding the constituent parts to each other with the bonding layer interposed therebetween, the thickness of the layered body in which the constituent parts are layered with the bonding layer interposed therebetween can be adjusted.

### Current Path in Light-Emitting Device 100

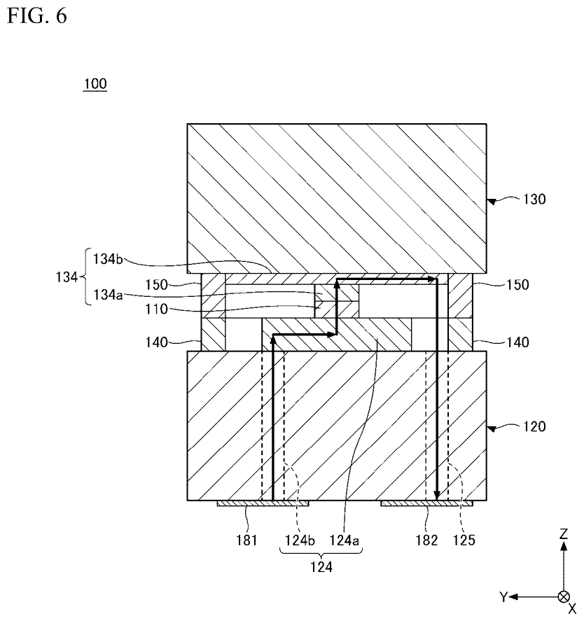

Next, a current path in the light-emitting device 100 will be described with reference to FIG. 6. FIG. 6 is a schematic cross-sectional view illustrating a cross section and a current path of the light-emitting device 100 taken along a cross-sectional line VI-VI in FIG. 1.

When the first electrode 181 is used as a positive electrode and the second electrode 182 is used as a negative electrode, a current flowing through the light-emitting device 100 may flow through the following path. As illustrated in FIG. 6, a current flows from the first electrode 181 to the light-emitting element 110 through the first inner layer wiring line 124b and the outer layer portion 124a of the first conductor portion 124 of the base 120 in this order. Further, the current flowing through the light-emitting device 100 passes through the first layer 134a and the second layer 134b of the second conductor portion 134 of the lid body 130 in this order, and then passes through the second frame portion 150 in contact with the second layer 134b, the first frame portion 140, and the second inner layer wiring line 125 in this order and flows to the second electrode 182.

In contrast, when the second electrode 182 is used as a positive electrode and the first electrode 181 is used as a negative electrode, the current flowing through the light-emitting device 100 may flow through the following path. The current flows from the second electrode 182 to the light-emitting element 110 through the second inner layer wiring line 125, the first frame portion 140, the second frame portion 150, the second layer 134b, and the first layer 134a in this order. Further, the current flowing through the light-emitting device 100 passes through the outer layer portion 124a and the first inner layer wiring line 124b in this order, and flows to the first electrode 181.

The light-emitting device 100 includes a current path in which the first electrode 181, the first conductor portion 124 of the base 120, the light-emitting element 110, the second conductor portion 134 of the lid body 130, the second frame portion 150, the first frame portion 140, and the second inner layer wiring line 125 of the base 120 are connected in series. That is, according to this configuration of the light-emitting device 100, it is possible to supply a current to the light-emitting element 110 without using a conductor wire such as a bonding wire disposed on an outer side of the base 120 and the lid body 130. The light-emitting element 110 is hermetically sealed in a space defined by the base 120, the lid body 130, the first frame portion 140, and the second frame portion 150. Thus, the number of components used to form the space for hermetically sealing the light-emitting element 110 can be reduced, and the manufacturing process of the light-emitting device 100 can be simplified. In addition, the first frame portion 140, the second frame portion 150, and the second inner layer wiring line 125, which are electrically connected to the light-emitting element 110 through the second conductor portion 134, are used as a part of the current path, so that the current path in the light-emitting device 100 can be shortened.

### Second Embodiment

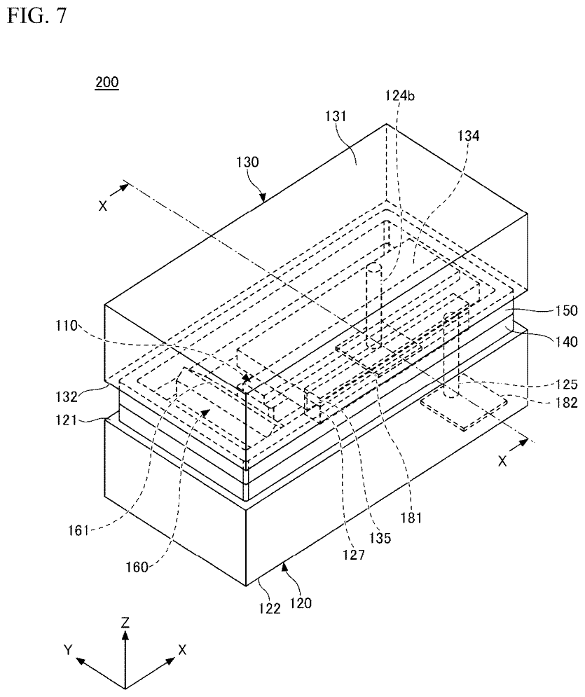

Next, a configuration example of the light-emitting device 200 according to the second embodiment will be described with reference to FIGS. 7 to 9. The light-emitting device 200 according to the second embodiment is different from the other embodiments in that the lid body 130 further includes a third conductor portion 135 and the base 120 further includes a fourth conductor portion 127.

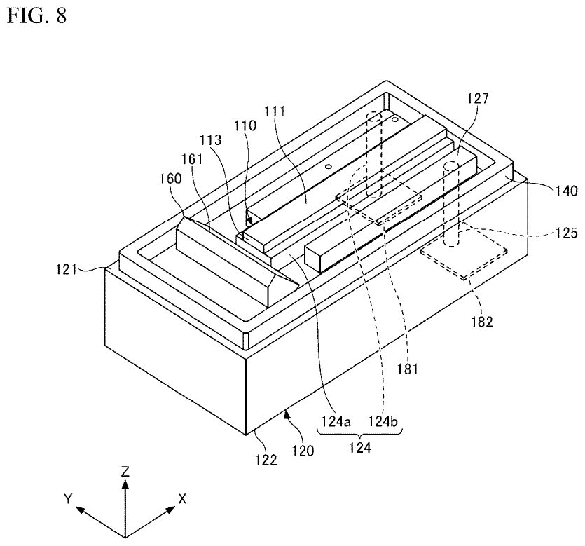

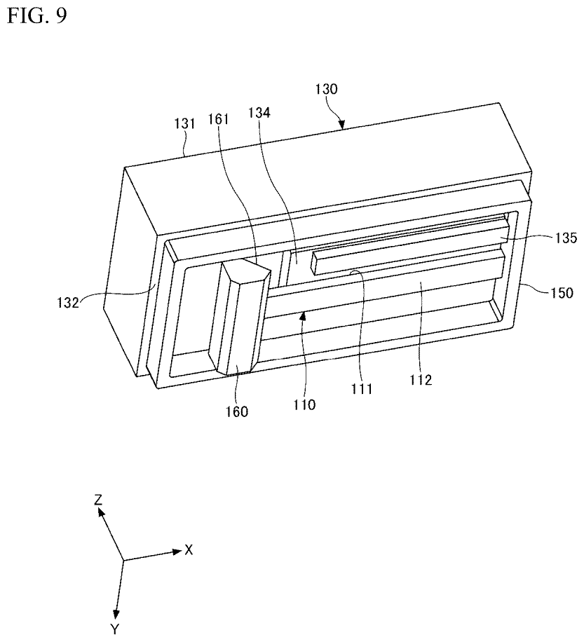

FIG. 7 is a schematic perspective view illustrating an example of a light-emitting device 200 according to the second embodiment. FIG. 8 is a schematic perspective view of the light-emitting device 200 illustrated in FIG. 7 from which the lid body 130 and the second frame portion 150 are removed. FIG. 9 is a schematic perspective view of the light-emitting device 200 illustrated in FIG. 7 from which the base 120 and the first frame portion 140 are removed.

As illustrated in FIG. 7, the light-emitting device 200 of the present embodiment includes the light-emitting element 110, the base 120, the lid body 130, the first frame portion 140, the second frame portion 150, the light reflective member 160, the first electrode 181, and the second electrode 182.

### Third Conductor Portion 135

As illustrated in FIG. 9, the lid body 130 further includes the third conductor portion 135. The third conductor portion 135 is a conductor portion connected to the lower surface (surface on the −Z direction side) of the second conductor portion 134. The lower surface of the second conductor portion 134 is bonded to the upper surface 111 of the light-emitting element 110 at a position different from the position of connection with the third conductor portion 135. That is, the light-emitting element 110 and the third conductor portion 135 are electrically connected via the second conductor portion 134.

The third conductor portion 135 has a strip-like outer shape extending along the X-direction. However, the outer shape of the third conductor portion 135 is not limited thereto. In the present embodiment, the thickness of the third conductor portion 135 is substantially the same as the thickness of the light-emitting element 110. However, the thickness of the third conductor portion 135 may be greater or smaller than the thickness of the light-emitting element 110.

The third conductor portion 135 is not in contact with the second frame portion 150. The second conductor portion 134 is also not in contact with the second frame portion 150. That is, each of the third conductor portion 135 and the second conductor portion 134 is not electrically connected to the second frame portion 150.

### Fourth Conductor Portion 127

As illustrated in FIG. 8, the base 120 further includes the fourth conductor portion 127. The fourth conductor portion 127 is a conductor portion provided on the upper surface 121 of the base 120. The lower surface (surface on the −Z direction side) of the fourth conductor portion 127 is connected to the upper end of the second inner layer wiring line 125 provided inside the base 120. Thus, the fourth conductor portion 127 is electrically connected to the second electrode 182 via the second inner layer wiring line 125.

Further, the upper surface (surface on the +Z direction side) of the fourth conductor portion 127 is bonded to the lower surface (surface on the −Z direction side) of the third conductor portion 135. Thus, the fourth conductor portion 127 and the third conductor portion 135 are electrically connected to each other. That is, the third conductor portion 135 is electrically connected to the second electrode 182 via the fourth conductor portion 127 and the second inner layer wiring line 125. The lower surface of the third conductor portion 135 may be directly bonded to the upper end of the second inner layer wiring line 125 without providing the fourth conductor portion 127.

The fourth conductor portion 127 has a strip-like outer shape such that the length in the X direction is greater than the length in the Y direction. However, the outer shape of the fourth conductor portion 127 is not limited thereto. The fourth conductor portion 127 of the present embodiment extends in the X direction, parallel to the outer layer portion 124a of the first conductor portion 124. However, the fourth conductor portion 127 and the outer layer portion 124a need not be parallel to each other.

In the present embodiment, the thickness of the fourth conductor portion 127 is substantially the same as the thickness of the outer layer portion 124a. However, the thickness of the fourth conductor portion 127 may be greater or smaller than the thickness of the outer layer portion 124a.

### Current Path in Light-emitting Device 200

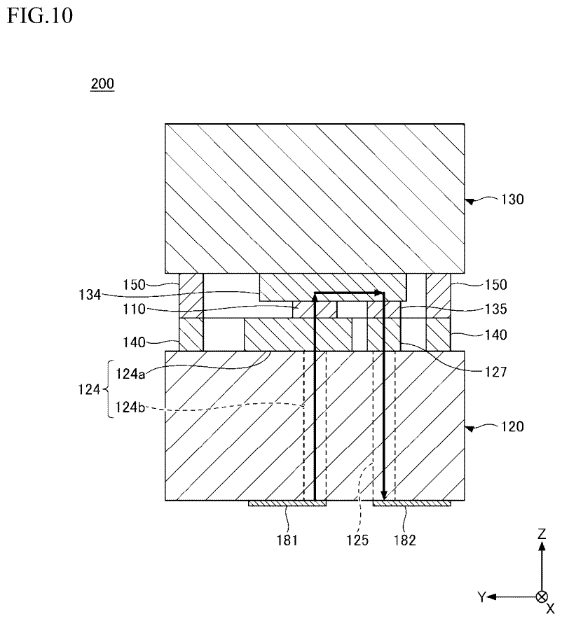

Next, a current path in the light-emitting device 200 will be described with reference to FIG. 10. FIG. 10 is a schematic cross-sectional view illustrating a cross section and a current path of the light-emitting device 200 taken along a cross-sectional line X-X in FIG. 7.

When the first electrode 181 is used as a positive electrode and the second electrode 182 is used as a negative electrode, a current flowing through the light-emitting device 200 may flow through the following path. As illustrated in FIG. 10, the current flows from the first electrode 181 to the light-emitting element 110 through the first inner layer wiring line 124b and the outer layer portion 124a of the first conductor portion 124 of the base 120 in this order. Furthermore, the current flowing in the light-emitting device 200 passes through the second conductor portion 134 and the third conductor portion 135 of the lid body 130, the fourth conductor portion 127 of the base 120, and the second inner layer wiring line 125 in this order, and flows to the second electrode 182.

In contrast, when the second electrode 182 is used as a positive electrode and the first electrode 181 is used as a negative electrode, the current flowing through the light-emitting device 200 may flow through the following path. The current flows from the second electrode 182 to the light-emitting element 110 through the second inner layer wiring line 125, the fourth conductor portion 127, the third conductor portion 135, and the second conductor portion 134 in this order. Further, the current flowing through the light-emitting device 200 passes through the outer layer portion 124a and the first inner layer wiring line 124b in this order, and flows to the first electrode 181.

The light-emitting device 200 includes a current path in which the first electrode 181, the first conductor portion 124 of the base 120, the light-emitting element 110, the second conductor portion 134 of the lid body 130, the third conductor portion 135, the fourth conductor portion 127 of the base 120, and the second inner layer wiring line 125 are connected in series. That is, unlike in the first embodiment, in the current path in the light-emitting device 200, a current does not pass through the first frame portion 140 and the second frame portion 150. According to this configuration of the light-emitting device 200, a current path for supplying a current to the light-emitting element 110 can be provided on an inner side of the first frame portion 140 and the second frame portion 150. Thus, the size of the light-emitting device 200 can be reduced, and the current path of the light-emitting device 200 can be further shortened. In addition, a space for hermetically sealing the light-emitting element 110 can be formed by the base 120, the lid body 130, the first frame portion 140, and the second frame portion 150. Therefore, the number of components used for forming the hermetically sealed space can be reduced, and the manufacturing process of the light-emitting device 200 can be simplified. The effects of the present embodiment other than those described above are similar to those of the first embodiment.

### Third Embodiment

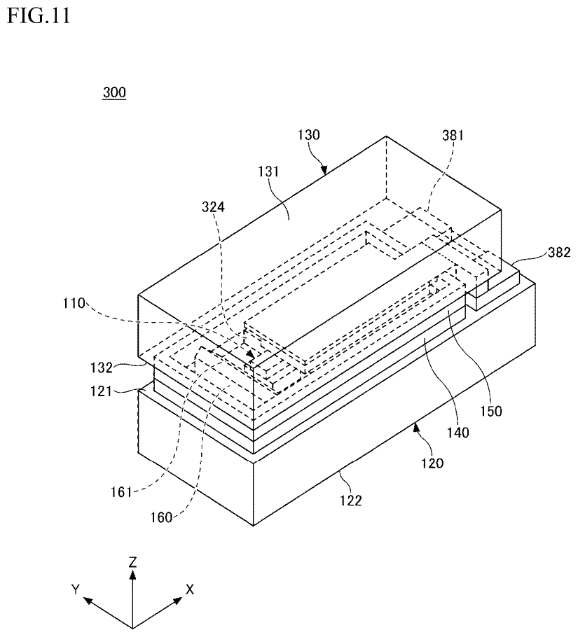

Next, a configuration example of a light-emitting device 300 according to the third embodiment will be described with reference to FIGS. 11 to 13. The light-emitting device 300 according to the third embodiment is different from the other embodiments in the positions of a first electrode 381 and a second electrode 382.

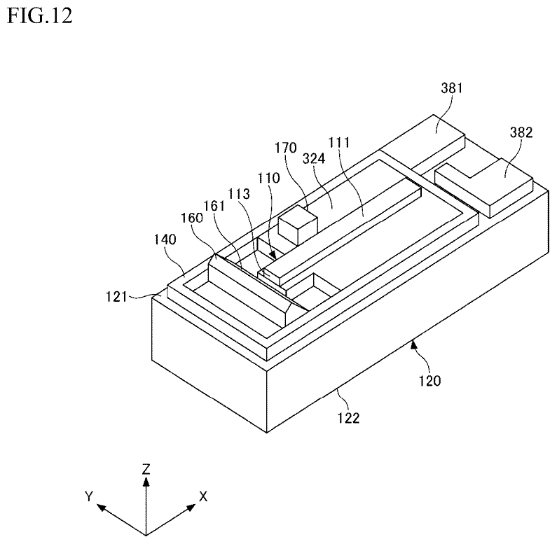

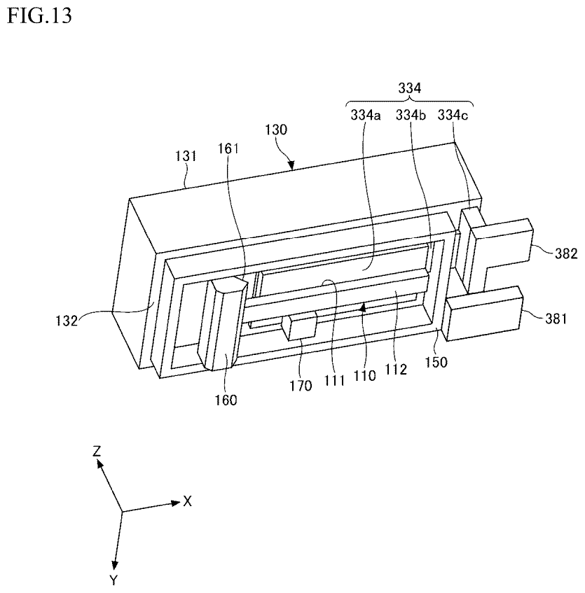

FIG. 11 is a schematic perspective view illustrating an example of the light-emitting device 300 according to the third embodiment. FIG. 12 is a schematic perspective view of the light-emitting device 300 illustrated in FIG. 11 from which the lid body 130 and the second frame portion 150 are removed. FIG. 13 is a schematic perspective view of the light-emitting device 300 illustrated in FIG. 11 from which the base 120 and the first frame portion 140 are removed.

As illustrated in FIG. 11, the light-emitting device 300 of the present embodiment includes the light-emitting element 110, the base 120, the lid body 130, the first frame portion 140, the second frame portion 150, the light reflective member 160, the first electrode 381, and the second electrode 382.

### First Electrode 381

As illustrated in FIGS. 11 and 12, the first electrode 381 is disposed on the upper surface 121 of the base 120. In addition, as illustrated in FIG. 12, the first electrode 381 is connected to a first conductor portion 324 disposed on the upper surface 121 of the base 120, via the first frame portion 140.

Unlike the first conductor portion 124 of the first embodiment and the second embodiment, the first conductor portion 324 of the present embodiment does not include the first inner layer wiring line 124b and the second inner layer wiring line 125. That is, unlike in the first embodiment and the second embodiment, the first conductor portion 324 and the first electrode 381 of the present embodiment are electrically connected to each other not via a wiring line portion provided inside the base 120.

An upper surface (surface on the +Z direction side) of the first conductor portion 324 is bonded to a lower surface of the light-emitting element 110. The light-emitting element 110 and the first electrode 381 are electrically connected via the first conductor portion 324. The upper surface of the first conductor portion 324 is bonded to the lower surface of the protective element 170 at a position different from the bonding position of the light-emitting element 110.

### Second Electrode 382

As illustrated in FIGS. 11 and 12, the second electrode 382 is disposed at a position different from that of the first electrode 381 on the upper surface 121 of the base 120. In the present embodiment, the first electrode 381 and the second electrode 382 are disposed adjacent to each other in the vicinity of the outer edge of the upper surface 121 on the +X direction side.

Unlike the first electrode 381, the second electrode 382 is not in contact with the first frame portion 140. As illustrated in FIG. 13, the second conductor portion 334 of the present embodiment includes a first layer 334a disposed on the upper surface 111 of the light-emitting element 110, a second layer 334b disposed between the first layer 334a and the lower surface 132 of the lid body 130, and a wall portion 334c connected to the second layer 334b. As illustrated in FIG. 13, the second electrode 382 is connected to the wall portion 334c of the second conductor portion 334. The light-emitting element 110 and the second electrode 382 are electrically connected via the second conductor portion 334.

The first layer 334a has a strip-like outer shape such that the length in the X direction is greater than the length in the Y direction. The second layer 334b has a flat plate-like outer shape such that the length in the Y direction is greater than the length in the Y direction of the first layer 334a. An end portion of the second layer 334b on the +X direction side extends so as to the wall portion 334c.

The lower surface (surface on the −Z direction side) of the second layer 334b is bonded to the upper surface of the protective element 170. However, when the light-emitting device 300 does not include the protective element 170, the second layer 334b may be omitted. In addition, when the thickness of the light-emitting element 110 and the thickness of the protective element 170 are the same as each other, the first layer 334a may be omitted, and the second layer 334b may be bonded to each of the light-emitting element 110 and the protective element 170.

The wall portion 334c is disposed on an outer side of the frame of the second frame portion 150, and is connected to the second electrode 382. On the other hand, the second layer 334b bonded to the wall portion 334c extends across the inner side and the outer side of the second frame portion 150 so as to reach the wall portion 334c. Therefore, in order to prevent a short circuit between the second layer 334b and the second frame portion 150, it is preferable to interpose an insulating film between the second layer 334b and the second frame portion 150.

### Current Path in Light-emitting Device 300

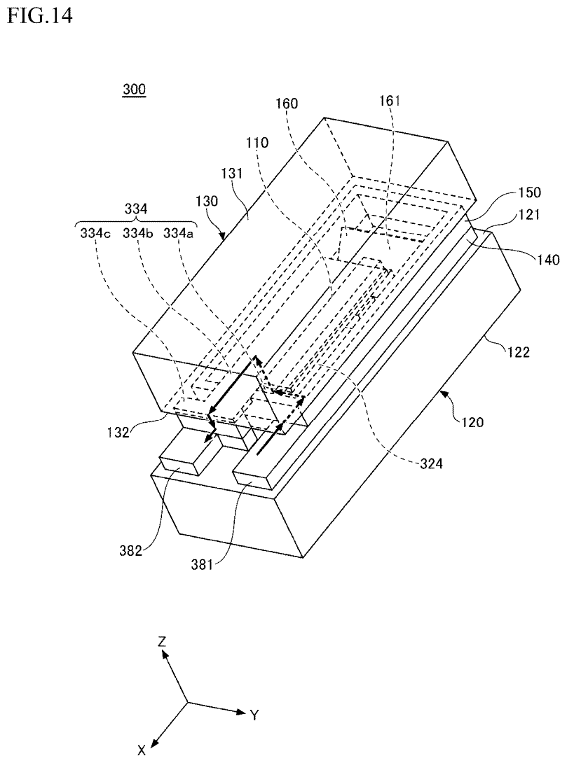

Next, a current path in the light-emitting device 300 will be described with reference to FIG. 14. FIG. 14 is a schematic transparent view illustrating the light-emitting device 300 and a current path as seen through the light-emitting element 110 inside.

When the first electrode 381 is used as a positive electrode and the second electrode 382 is used as a negative electrode, a current flowing through the light-emitting device 300 may flow through the following path. As illustrated in FIG. 14, the current flows from the first electrode 381 to the light-emitting element 110 through the first conductor portion 324 of the base 120. Furthermore, the current flowing through the light-emitting device 300 passes through the first layer 334a, the second layer 334b, and the wall portion 334c of the second conductor portion 334 of the lid body 130 in this order, and flows to the second electrode 382.

In contrast, when the second electrode 382 is used as a positive electrode and the first electrode 381 is used as a negative electrode, the current flowing through the light-emitting device 300 may flow through the following path. The current flows from the second electrode 382 to the light-emitting element 110 through the wall portion 334c, the second layer 334b, and the first layer 334a in order. Further, the current flowing through the light-emitting device 300 flows through the first conductor portion 324 to the first electrode 381.

In the light-emitting device 300, since each of the first electrode 381 and the second electrode 382 is provided on the upper surface 121 of the base 120, the base 120 can be directly mounted on a heat dissipation member such as a heat sink. Thus, heat dissipation of the light-emitting device 300 can be improved.

Each of the first electrode 381, the second electrode 382, and the light-emitting element 110 is supported by the upper surface 121 of the base 120. That is, the first electrode 381, the second electrode 382, and the light-emitting element 110 are disposed at positions close to each other. Thus, the current path in the light-emitting device 300 can be shortened, and the electrical resistance in the current path can be reduced. In addition, a space for hermetically sealing the light-emitting element 110 can be formed by the base 120, the lid body 130, the first frame portion 140, and the second frame portion 150. Therefore, the number of components used for forming the hermetically sealed space can be reduced, and the manufacturing process of the light-emitting device 300 can be simplified. The effects of the present embodiment other than those described above are similar to those of the first embodiment and the second embodiment.

### Fourth Embodiment

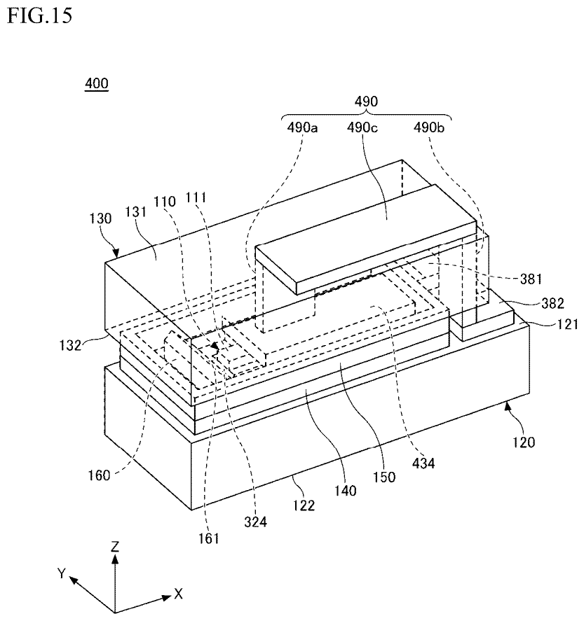

Next, a configuration example of a light-emitting device 400 according to the fourth embodiment will be described with reference to FIG. 15. The light-emitting device 400 according to the fourth embodiment is different from the other embodiments in that a fifth conductor portion 490 is provided. FIG. 15 is a schematic perspective view illustrating an example of the light-emitting device 400 according to the fourth embodiment.

As illustrated in FIG. 15, the light-emitting device 400 of the present embodiment includes the light-emitting element 110, the base 120, the lid body 130, the first frame portion 140, the second frame portion 150, the fifth conductor portion 490, the light reflective member 160, the first electrode 381, and the second electrode 382.

### Fifth Conductor Portion 490

The fifth conductor portion 490 is a conductor portion for electrically connecting a second conductor portion 434 of the lid body 130 and the second electrode 382. The fifth conductor portion 490 includes a first column portion 490a extending in the Z direction inside the lid body 130 from the upper surface (surface on the +Z direction side) of the second conductor portion 434, a second column portion 490b extending in the Z direction inside the lid body 130 from the upper surface (surface on the +Z direction side) of the second electrode 382, and a beam portion 490c connecting the first column portion 490a and the second column portion 490b.

Each of the first column portion 490a, the second column portion 490b, and the beam portion 490c has a rectangular parallelepiped outer shape, but may have another shape. The beam portion 490c is exposed above the upper surface 131 of the lid body 130, but may be provided inside the lid body 130. That is, all the portions included in the fifth conductor portion 490 may be provided inside the lid body 130. In this case, the thickness of the second electrode 382 in the Z direction is the sum of the thickness of the first frame portion 140 in the Z direction and the thickness of the second frame portion 150 in the Z direction.

As illustrated in FIG. 15, the lateral surface of the lid body 130 on the +X direction side is disposed on an outer side of the second frame portion 150. The fifth conductor portion 490 is provided straddling the second frame portion 150. That is, the beam portion 490c crosses the second frame portion 150 in a state in which the beam portion 490c and the second frame portion 150 are spatially separated from each other. In addition, in a case in which the light-emitting device 400 does not include the second frame portion 150 and the first frame portion 140 and the lid body 130 are bonded to each other, the fifth conductor portion 490 is provided straddling the first frame portion 140.

The second conductor portion 434 disposed between the lower surface 132 of the lid body 130 and the upper surface 111 of the light-emitting element 110 has a flat plate-like outer shape. However, the outer shape of the second conductor portion 434 is not limited thereto.

### Current Path in Light-Emitting Device 400

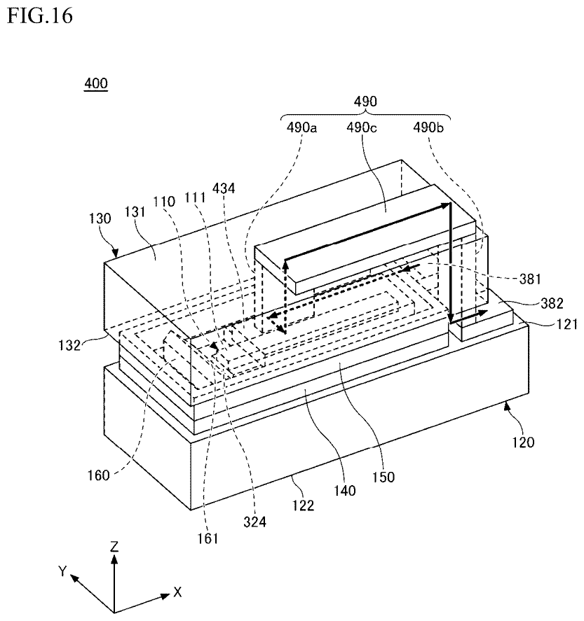

Next, a current path in the light-emitting device 400 will be described with reference to FIG. 16. FIG. 16 is a schematic transparent view illustrating the light-emitting device 400 and a current path as seen through the light-emitting element 110 inside.

When the first electrode 381 is used as a positive electrode and the second electrode 382 is used as a negative electrode, a current flowing through the light-emitting device 400 may flow through the following path. As illustrated in FIG. 16, the current flows from the first electrode 381 to the light-emitting element 110 through the first conductor portion 324 of the base 120. Further, the current flowing through the light-emitting device 400 passes through the second conductor portion 434 and the fifth conductor portion 490 of the lid body 130 in order, and flows to the second electrode 382.

In contrast, when the second electrode 382 is used as a positive electrode and the first electrode 381 is used as a negative electrode, the current flowing through the light-emitting device 400 may flow through the following path. The current flows from the second electrode 382 through the fifth conductor portion 490 and the second conductor portion 434 to the light-emitting element 110. Further, the current flowing through the light-emitting device 400 flows through the first conductor portion 324 to the first electrode 381.

The light-emitting device 400 includes the fifth conductor portion 490 having a structure straddling the second frame portion 150 as a conductor portion for electrically connecting the second conductor portion 434 and the second electrode 382. Accordingly, it is possible to prevent a short circuit between the fifth conductor portion 490 and the second frame portion 150 without interposing an insulating member such as an insulating film between the fifth conductor portion 490 and the second frame portion 150. In addition, in a case in which the light-emitting device 400 does not include the second frame portion 150 and the first frame portion 140 and the lid body 130 are bonded to each other, the fifth conductor portion 490 is provided straddling the first frame portion 140. Accordingly, it is possible to prevent a short circuit between the fifth conductor portion 490 and the first frame portion 140 without interposing an insulating member such as an insulating film between the fifth conductor portion 490 and the first frame portion 140. In addition, a space for hermetically sealing the light-emitting element 110 can be formed by the base 120, the lid body 130, the first frame portion 140, and the second frame portion 150. Therefore, the number of components used for forming the hermetically sealed space can be reduced, and the manufacturing process of the light-emitting device 400 can be simplified. The effects of the present embodiment other than those described above are similar to those of the third embodiment.

### Fifth Embodiment

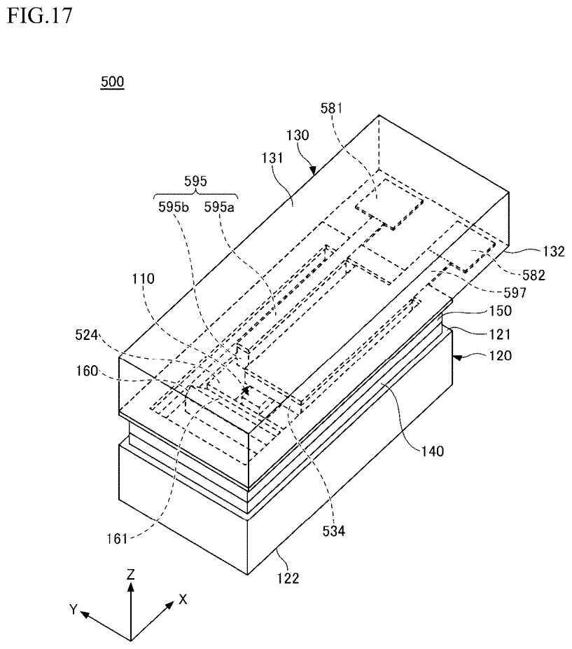

Next, a configuration example of a light-emitting device 500 according to the fifth embodiment will be described with reference to FIG. 17. The light-emitting device 500 according to the fifth embodiment is different from the other embodiments in that a first electrode 581 and a second electrode 582 are provided on the lower surface 132 of the lid body 130.

FIG. 17 is a schematic perspective view illustrating an example of the light-emitting device 500 according to a fifth embodiment.

As illustrated in FIG. 17, the light-emitting device 500 of the present embodiment includes the light-emitting element 110, the base 120, the lid body 130, the first frame portion 140, the second frame portion 150, the light reflective member 160, the first electrode 581, and the second electrode 582.

### First Electrode 581

The first electrode 581 is provided on the lower surface 132 of the lid body 130. Here, the base 120 further includes a sixth conductor portion 595. The sixth conductor portion 595 is a conductor portion for electrically connecting the first electrode 581 and the first conductor portion 524 of the base 120.

As illustrated in FIG. 17, the sixth conductor portion 595 includes a first layer 595a extending from the first electrode 581 in the X direction along the lower surface 132 of the lid body 130, and a second layer 595b disposed between the lower surface (surface on the −Z direction side) of the first layer 595a and the first conductor portion 524.

The first layer 595a extends from the outer side of the second frame portion 150 on which the first electrode 581 is disposed to the inner side of the second frame portion 150 on which the second layer 595b is disposed, extending across the outer side and the inner side of the second frame portion 150. In order to prevent a short circuit between the first layer 595a and the second frame portion 150, an insulating film is preferably interposed between the first layer 595a and the second frame portion 150.

### Second Electrode 582

The second electrode 582 is provided on the lower surface 132 of the lid body 130. Here, the lid body 130 further includes a seventh conductor portion 597. The seventh conductor portion 597 is a conductor portion for electrically connecting the second electrode 582 and the second conductor portion 534 of the lid body 130.

As illustrated in FIG. 17, the seventh conductor portion 597 extends from the second electrode 582 in the X direction along the lower surface 132 of the lid body 130, and is bonded to the upper surface (surface on the +Z direction side) of the second conductor portion 534. That is, the seventh conductor portion 597 extends from the outer side of the second frame portion 150 on which the second electrode 582 is disposed to the inner side of the second frame portion 150 on which the second conductor portion 534 is disposed, extending across the outer side to the inner side of the second frame portion 150. In order to prevent a short circuit between the seventh conductor portion 597 and the second frame portion 150, an insulating film is preferably interposed between the seventh conductor portion 597 and the second frame portion 150.

### Current Path in Light-Emitting Device 500

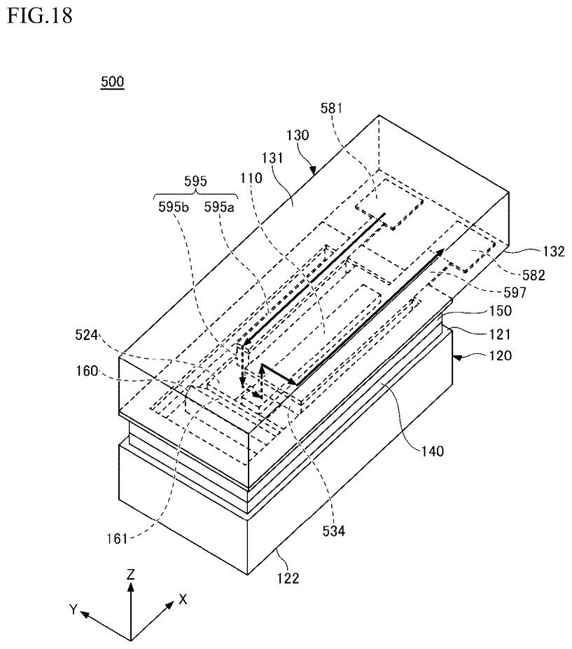

Next, a current path in the light-emitting device 500 will be described with reference to FIG. 18. FIG. 18 is a schematic transparent view illustrating the light-emitting device 500 and a current path as seen through the light-emitting element 110 inside.

In the case in which the first electrode 581 is used as a positive electrode and the second electrode 582 is used as a negative electrode, a current flowing through the light-emitting device 500 may flow through the following path. As illustrated in FIG. 18, the current flows from the first electrode 581 to the light-emitting element 110 through the sixth conductor portion 595 in the lid body 130 and the first conductor portion 524 in the base 120 in order. Further, the current flowing through the light-emitting device 500 passes through the second conductor portion 534 and the seventh conductor portion 597 in the lid body 130 in order, and flows to the second electrode 582.

In contrast, when the second electrode 582 is used as a positive electrode and the first electrode 581 is used as a negative electrode, a current flowing through the light-emitting device 500 may flow through the following path. The current flows from the second electrode 582 to the light-emitting element 110 through the seventh conductor portion 597 and the second conductor portion 534 in this order. Further, the current flowing through the light-emitting device 500 passes through the first conductor portion 524 and the sixth conductor portion 595 in this order, and flows to the first electrode 581.

Each of the first electrode 581 and the second electrode 582 is bonded to the lower surface 132 of the lid body 130 and is protected by the lid body 130. Thus, the durability of the first electrode 581 and the second electrode 582 can be improved. In addition, a space for hermetically sealing the light-emitting element 110 can be formed by the base 120, the lid body 130, the first frame portion 140, and the second frame portion 150. Therefore, the number of components used for forming the hermetically sealed space can be reduced, and the manufacturing process of the light-emitting device 500 can be simplified. The effects of the present embodiment other than those described above are similar to those of the third embodiment.

### Sixth Embodiment

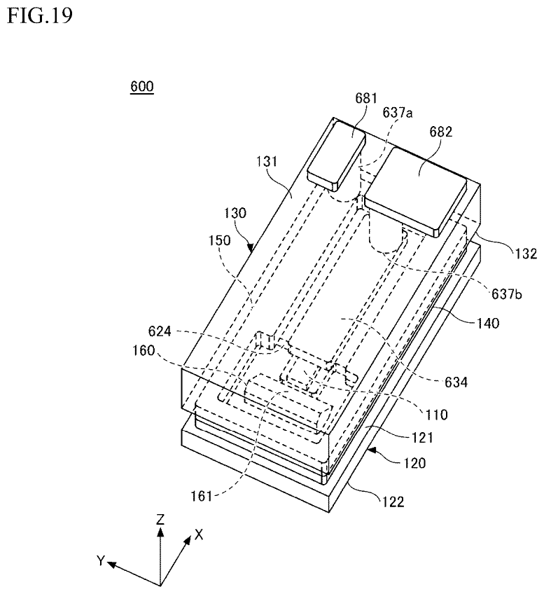

Next, a configuration example of a light-emitting device 600 according to the sixth embodiment will be described with reference to FIG. 19. The light-emitting device 600 according to the sixth embodiment is different from the other embodiments in that a first electrode 681 and a second electrode 682 are provided on the upper surface 131 of the lid body 130. FIG. 19 is a schematic perspective view illustrating an example of the light-emitting device 600 according to the sixth embodiment.

As illustrated in FIG. 19, the light-emitting device 600 of the present embodiment includes the light-emitting element 110, the base 120, the lid body 130, the first frame portion 140, the second frame portion 150, the light reflective member 160, the first electrode 681, and the second electrode 682.

The first electrode 681 and the second electrode 682 are disposed at different positions on the upper surface 131 of the lid body 130. The lid body 130 includes inner layer wiring lines 637a and 637b. The inner layer wiring lines 637a and 637b are provided inside the lid body 130.

The first electrode 681 is connected to an upper end (end portion on the +Z direction side) of the inner layer wiring line 637a. A lower end (end portion on the −Z direction side) of the inner layer wiring line 637a is connected to the second frame portion 150. The second frame portion 150 is bonded to the first frame portion 140. The first frame portion 140 is connected to the first conductor portion 624 of the base 120. The first conductor portion 624 is bonded to the light-emitting element 110. Thus, the first electrode 681 and the light-emitting element 110 are electrically connected to each other.

The second electrode 682 is connected to an upper end (end portion on the +Z direction side) of the inner layer wiring line 637b. A lower end (end portion on the −Z direction side) of the inner layer wiring line 637b is connected to the second conductor portion 634 of the lid body 130. The second conductor portion 634 is bonded to the light-emitting element 110. Thus, the second electrode 682 and the light-emitting element 110 are electrically connected to each other.

### Current Path in Light-emitting Device 600

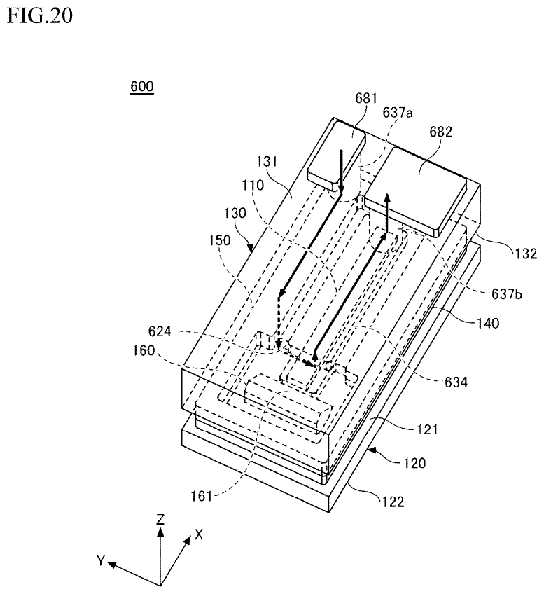

Next, a current path in the light-emitting device 600 will be described with reference to FIG. 20. FIG. 20 is a schematic transparent view illustrating the light-emitting device 600 and a current path as seen through the light-emitting element 110 inside.

In the case in which the first electrode 681 is used as a positive electrode and the second electrode 682 is used as a negative electrode, a current flowing through the light-emitting device 600 may flow through the following path. As illustrated in FIG. 20, the current flows from the first electrode 681 to the light-emitting element 110 through the inner layer wiring line 637a of the lid body 130, the second frame portion 150, the first frame portion 140, and the first conductor portion 624 of the base 120 in this order. Further, the current flowing through the light-emitting device 600 passes through the second conductor portion 634 and the inner layer wiring line 637b in the lid body 130 in this order, and flows to the second electrode 682.

In contrast, when the second electrode 682 is used as a positive electrode and the first electrode 681 is used as a negative electrode, the current flowing through the light-emitting device 600 may flow through the following path. The current flows from the second electrode 682 to the light-emitting element 110 through the inner layer wiring line 637b and the second conductor portion 634 in this order. Further, the current flowing through the light-emitting device 600 passes through the first conductor portion 624, the first frame portion 140, the second frame portion 150, and the inner layer wiring line 637a in this order, and flows to the first electrode 681.

Since each of the first electrode 681 and the second electrode 682 is provided on the upper surface 131 of the lid body 130, the first electrode 681 and the second electrode 682 can be provided without increasing the size of the lid body 130. Thus, the size of the light-emitting device 600 can be reduced. In addition, a space for hermetically sealing the light-emitting element 110 can be formed by the base 120, the lid body 130, the first frame portion 140, and the second frame portion 150. Therefore, the number of components used for forming the hermetically sealed space can be reduced, and the manufacturing process of the light-emitting device 600 can be simplified. The effects of the present embodiment other than those described above are similar to those of the third embodiment.

### Seventh Embodiment

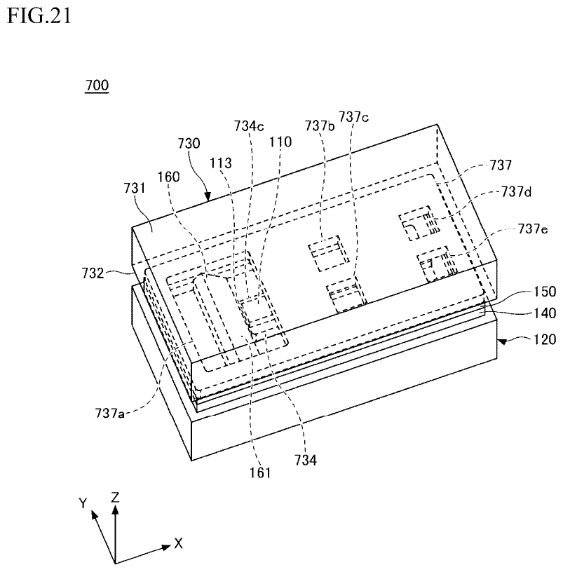

Next, a configuration example of a light-emitting device 700 according to the seventh embodiment will be described with reference to FIG. 21. The light-emitting device 700 according to the seventh embodiment is different from the other embodiments in the configuration of a lid body 730. FIG. 21 is a schematic perspective view illustrating an example of the light-emitting device 700 according to the seventh embodiment.

As illustrated in FIG. 21, the light-emitting device 700 of the present embodiment includes the light-emitting element 110, the base 120, the lid body 730, the first frame portion 140, the second frame portion 150, and the light reflective member 160. The light-emitting device 700 further includes a first electrode and a second electrode for supplying current to the light-emitting element 110.

The lid body 730 includes a light shielding portion 737. The light shielding portion 737 is provided on at least one of an upper surface 731 and a lower surface 732 of the lid body 730. The light shielding portion 737 of the present embodiment is provided on the lower surface 732 of the lid body 730.

A region of the lid body 730 where the light shielding portion 737 is not provided is a light-transmitting region. For example, an opening is provided in each of a plurality of regions of the light shielding portion 737. The plurality of openings provided in the light shielding portion 737 respectively correspond to light-transmitting regions 737a to 737e in the lid body 730.

The light-transmitting region 737a is located above the light-emitting surface 113 of the light-emitting element 110 and the light reflective member 160. The light-transmitting region 737a is a region through which light emitted from the light-emitting element 110 passes. Hereinafter, a light-transmitting region through which light emitted from the light-emitting element 110 passes, such as the light-transmitting region 737a, is referred to as a “first light-transmitting region.”

On the other hand, the light-transmitting regions 737b and 737c are located above the central portion of the light-emitting element 110. That is, the central portion of the light-emitting element 110 can be visually recognized through the light-transmitting regions 737b and 737c. In addition, the light-transmitting regions 737d and 737e are located above the end portion of the light-emitting element 110 on the +X direction side. That is, the end portion of the light-emitting element 110 on the +X direction side can be visually recognized through the light-transmitting regions 737d and 737e. The light-transmitting regions, such as the light-transmitting regions 737b, 737c, 737d, and 737e, which are disposed at positions where regions not including the light-emitting surface 113 of the light-emitting element 110 can be visually recognized, are hereinafter referred to as “second light-transmitting regions.” The number of first light-transmitting regions is not limited. In addition, the number of second light-transmitting regions is not limited.

A bonding layer 734c formed by curing a conductive adhesive is disposed between the light-emitting element 110 and the first conductor portion 734. By disposing the first light-transmitting region 737a and the second light-transmitting regions 737b to 737e such that a plurality of regions of the light-emitting element 110 in the X direction can be visually recognized, the degree of spread of the bonding layer 734c between the light-emitting element 110 and the first conductor portion 734 can be visually recognized. Thus, a bonding failure between the light-emitting element 110 and the first conductor portion 734 can be confirmed. In addition, a space for hermetically sealing the light-emitting element 110 can be formed by the base 120, the lid body 130, the first frame portion 140, and the second frame portion 150. Therefore, the number of components used for forming the hermetically sealed space can be reduced, and the manufacturing process of the light-emitting device 700 can be simplified. The effects of the present embodiment other than those described above are similar to those of the first embodiment.

Although the preferred embodiments and the like have been described in detail above, the disclosure is not limited to the above-described embodiments and the like, various modifications and substitutions can be made to the above-described embodiments and the like without departing from the scope described in the claims.

The light-emitting device according to the present disclosure can be applied to a light source such as a projector, an in-vehicle headlight, an illumination, and backlights of a head-mounted display and other displays.

1. A light-emitting device comprising:
a light-emitting element;
a base having an upper surface opposite to a lower surface of the light-emitting element, the base directly or indirectly supporting the light-emitting element;
a lid body having a flat plate-like shape and having a lower surface opposite to an upper surface of the light-emitting element; and
a first frame portion located on the upper surface of the base and surrounding the light-emitting element, wherein:
the base comprises a first conductor portion bonded to the lower surface of the light-emitting element,
the lid body comprises a second conductor portion bonded to the upper surface of the light-emitting element, and
the first frame portion is directly or indirectly bonded to the lid body.

2. The light-emitting device according to claim 1, further comprising:
a second frame portion located on the lower surface of the lid body and directly bonded to the first frame portion.

3. The light-emitting device according to claim 2, wherein:
the light-emitting element is hermetically sealed in a space defined by the base, the lid body, the first frame portion, and the second frame portion.

4. The light-emitting device according to claim 2, further comprising:
bonding layers formed by curing an adhesive, the bonding layers being respectively disposed between the lower surface of the light-emitting element and the first conductor portion, between the upper surface of the light-emitting element and the second conductor portion, and between the first frame portion and the second frame portion.

5. The light-emitting device according to claim 1, further comprising:
a light reflective member disposed on the upper surface of the base, the light reflective member being configured to reflect light emitted from the light-emitting element toward the lid body.

6. The light-emitting device according to claim 1, wherein:
the first frame portion comprises a conductive region, and
the conductive region is a part of a current path through which a current flows to the light-emitting element.

7. The light-emitting device according to claim 1, wherein:
the lid body comprises a third conductor portion protruding from the second conductor portion toward the upper surface of the base,
the base comprises a fourth conductor portion bonded to the third conductor portion, and
the third conductor portion and the fourth conductor portion are parts of a current path through which a current flows to the light-emitting element.

8. The light-emitting device according to claim 1, further comprising:
a first electrode electrically connected to the first conductor portion; and
a second electrode electrically connected to the second conductor portion, wherein:
the first electrode is disposed on a lower surface of the base, and
the first conductor portion comprises:
an outer layer portion disposed between the upper surface of the base and the lower surface of the light-emitting element; and
an inner layer wiring line located inside the base and bonded to each of the outer layer portion and the first electrode.

9. The light-emitting device according to claim 1, further comprising:
a first electrode electrically connected to the first conductor portion; and
a second electrode electrically connected to the second conductor portion, wherein:
the first electrode and the second electrode are each disposed on the upper surface of the base.

10. The light-emitting device according to claim 1, further comprising:
a first electrode electrically connected to the first conductor portion; and
a second electrode electrically connected to the second conductor portion, wherein:
the first electrode and the second electrode are each disposed on an upper surface of the lid body.

11. The light-emitting device according to claim 1, further comprising:
a first electrode electrically connected to the first conductor portion; and
a second electrode electrically connected to the second conductor portion, wherein:
the first electrode and the second electrode are each disposed on the lower surface of the lid body.

12. The light-emitting device according to claim 9, wherein
the lid body further comprises a fifth conductor portion bonded to each of the second conductor portion and the second electrode, the fifth conductor portion straddling the first frame portion, and
at least a part of the fifth conductor portion is located inside the lid body.

13. The light-emitting device according to claim 12, further comprising:
a second frame portion located on the lower surface of the lid body and directly bonded to the first frame portion, wherein:
the fifth conductor portion straddles the second frame portion.

14. The light-emitting device according to claim 1, wherein:
the lid body comprises a light shielding portion on at least one of an upper surface and the lower surface,
the lid body comprises a plurality of light-transmitting regions in which the light shielding portion is not located, in a top view, and
the plurality of light-transmitting regions include first light-transmitting region through which light emitted from the light-emitting element passes, and at least one second light-transmitting region disposed at a position at which a region that does not comprise a light-emitting surface of the light-emitting element is visible.
